(19) United States
(12) Patent Application Publication
(10) Pub. No.: US 2022/0178024 A1
(43) Pub. Date: Jun. 9, 2022

(54) FURNACE WITH METAL FURNACE TUBE

(71) Applicant: Tokyo Electron Limited, Tokyo (JP)

(72) Inventors: Melvin Verbaas, Nirasaki City (JP); Anthony Dip, Austin, TX (US)

(21) Appl. No.: 17/114,096

(22) Filed: Dec. 7, 2020

(51) Int. Cl. C23C 16/455; C23C 16/46; F27D 1/16; F27D 1/00; C23C 16/40; C23C 16/34

(52) U.S. Cl. CPC C23C 16/45544; C23C 16/46; F27D 1/1684; F27M 2003/17; C23C 16/403; C23C 16/34; F27D 1/0006

(57) ABSTRACT

An exemplary apparatus includes a metal furnace tube having an open first end and an opposite second end. The metal furnace tube includes an inner chamber, a fluid inlet to intake a fluid into the inner chamber, and a fluid outlet to exhaust the fluid from the inner chamber, the inner chamber to support a plurality of substrates within the metal furnace tube. The apparatus includes a first base plate or flange back plate coupling the fluid inlet to the inner chamber; a second base plate or flange back plate coupling the fluid outlet to the inner chamber; and a furnace includes a heater to heat the metal furnace tube, the metal furnace tube being mounted within the furnace and the heater being disposed outside the metal furnace tube.

### TECHNICAL FIELD

The present invention relates generally to a system and method for processing semiconductor substrates, and, in particular embodiments, to a system and method for processing a batch of semiconductor substrates in a furnace tube.

### BACKGROUND

Semiconductor substrates such as semiconductor wafers can be processed individually in single wafer processing tools or can be processed many-at-a-time in batch wafer processing tools. Processes can include thin film depositions such as chemical vapor depositions (CVD), epitaxial growth of single crystal semiconductor layers, dielectric growth such as the oxidation of silicon to form silicon dioxide, and thermal anneals during the formation of buried diffusions and during hydrogen and forming gas sinters. Semiconductor furnace can be cold wall or hot wall furnaces. In cold wall furnaces, the temperature of the semiconductor substrates is different than the temperature of the inside wall of the furnace tube. In hot wall furnaces, the temperature of the semiconductor substrates is generally equal to the temperature of the inside wall of the furnace tube. Most single wafer furnaces are cold wall and most batch furnaces are hot wall.

In batch semiconductor wafer processing tools, multiple wafers are lined up in slots in a wafer boat and loaded into the furnace tube in a furnace cabinet. The furnace tube can be a horizontal furnace tube in a horizontal furnace cabinet or can be a vertical furnace tube in a vertical furnace cabinet. In horizontal furnace tubes, multiple wafers are lined up next to each other separated by gaps and are processed in a vertical orientation. Slight temperature variation from bottom to top across especially large diameter wafers in horizontal furnace tubes can result in slight across wafer non uniformity. In vertical furnace tubes, multiple wafers are stacked vertically one above the other separated by gaps and processed in a horizontal orientation.

### SUMMARY

In an embodiment, an apparatus comprises a metal furnace tube having an open first end and an opposite second end. The metal furnace tube comprises an inner chamber, a fluid inlet configured to intake a fluid into the inner chamber, and a fluid outlet configured to exhaust the fluid from the inner chamber, the inner chamber configured to support a plurality of substrates within the metal furnace tube. The apparatus comprises a first base plate or flange back plate coupling the fluid inlet to the inner chamber; a second base plate or flange back plate coupling the fluid outlet to the inner chamber; and a furnace comprising a heater configured to heat the metal furnace tube, the metal furnace tube being mounted within the furnace and the heater being disposed outside the metal furnace tube.

In an embodiment, a method comprises having a metal furnace tube, the metal furnace tube comprising an inner chamber to house a plurality of substrates, a fluid inlet configured to intake a fluid into the inner chamber, and a fluid outlet configured to exhaust the fluid from the inner chamber. The method includes having a tube flange at a first end of the metal furnace tube, mounting the metal furnace tube in a furnace configured to heat the metal furnace tube, having a base plate or a flange back plate in the furnace, and mating the tube flange with the base plate or the flange back plate.

In an embodiment, a method includes removing a glass or quartz furnace tube from a furnace from a tube mounting location of the furnace; mounting a metal furnace tube in the furnace at the tube mounting location, the metal furnace tube comprising an inner chamber to house a plurality of substrates, a fluid inlet configured to intake a fluid into the inner chamber, and a fluid outlet configured to exhaust the fluid from the inner chamber; and attaching a tube flange at a first end of the metal furnace tube to a base plate or to a flange back plate in the furnace.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 illustrates a cross-sectional view of a horizontal furnace for processing semiconductor substrates and configured for metal furnace tubes or for quartz furnace tubes in accordance with an embodiment of the present application;

FIG. 2 is a projection view of the backing plate for the horizontal furnace illustrated in FIG. 1 in accordance with an embodiment of the present application;

FIG. 3 illustrates a cross-sectional view of a horizontal furnace for processing semiconductor substrates and configured for furnace tubes with metal flanges in accordance with an embodiment of the present application;

FIG. 4 is a projection view of a metal furnace tube for the horizontal furnace illustrated in FIG. 3 in accordance with an embodiment of the present application;

FIG. 5 illustrates a cross section of a vertical furnace with a fluid inlet and a fluid outlet located at the base and configured for either a metal furnace tube or a quartz tube in accordance with an embodiment of the present application;

FIG. 6 illustrates a cross section of a vertical furnace with a fluid inlet and a fluid outlet located in the base plate and configured for a metal furnace tube with a metal flange in accordance with an embodiment of the present application;

FIG. 7 illustrates a cross section of a vertical furnace with a fluid inlet located in the base plate, a fluid outlet located at the top and configured for either a metal furnace tube or a quartz tube in accordance with an embodiment of the present application;

FIG. 8 illustrates a cross section of a vertical furnace with a fluid inlet located in the base plate, a fluid outlet located at the top and configured for an embodiment metal furnace tube with a metal flange in accordance with an embodiment of the present application;

FIG. 9 is a flow diagram of a method of making a metal furnace tube that replaces a quartz tube in a furnace cabinet and a method for processing semiconductor substrates therein in accordance with an embodiment of the present application; and

FIG. 10 is a flow diagram of a method of making a furnace system with a metal furnace tube with a metal flange and a method for processing semiconductor substrates therein in accordance with an embodiment of the present application.

### DETAILED DESCRIPTION OF ILLUSTRATIVE EMBODIMENTS

Systems and methods are provided herein for the batch processing of semiconductor substrates in metal furnace tubes.

As will be evident from the detailed discussion of various embodiments below, metal furnace tubes offer a number of advantages over glass furnace tubes such as fused quartz and Pyrex. Metal furnace tube material is less expensive and metal furnace tubes are less expensive to fabricate. Metal furnace tubes are much less fragile. Metal furnace tubes can be fabricated with more complex shapes. Metal furnace tubes can be fabricated with flanges eliminating the more expensive clamping systems used to transition from glass furnace tubes to the metal fluid inlet manifold and to the metal fluid exhaust manifold. The inside surface of metal tubes can be easily roughened to increase surface area for improved adhesion of layers being deposited. This enables more layers to be deposited between periodic cleaning of the furnace tube, thereby reducing manufacturing cost. The coefficient of thermal expansion (CTE) between a metal furnace tube and the thin film being deposited is more closely matched than the CTE between a quartz or Pyrex furnace tube and the deposited thin film layers. With better matched CTE's, stress between the deposited thin film layers and the metal furnace tube is reduced, especially during the temperature changes when loading and unloading wafers. Reduced stress translates into reduced delamination and flaking of the deposited thin film. Reduced flaking translates into reduced particles, reduced defects, and higher yield. The improved CTE matching between the thin film being deposited and the metal furnace tube enables thicker layers of thin film to be deposited before the furnace tube is pulled to remove film buildup. For example, the CTE of aluminum oxide is better matched to an aluminum furnace tube than to a quartz tube. Likewise, the CTE of titanium nitride is better matched to a titanium furnace tube than to a quartz tube.

As discussed in various embodiments, metal furnace tubes can be fabricated to replace quartz tubes without changes to the furnace cabinet. The furnace system cost can be additionally reduced by welding tube flanges to the ends of the metal furnace tube and modifying the furnace cabinet to accept the metal furnace tubes with flanges.

The embodiment furnace systems significantly reduce cost of ownership (CoO) by reducing the initial cost of the furnace system, reducing tube breakage, reducing the cost of tube replacement, reducing maintenance costs, and extending the time between tube pulls and tube cleaning.

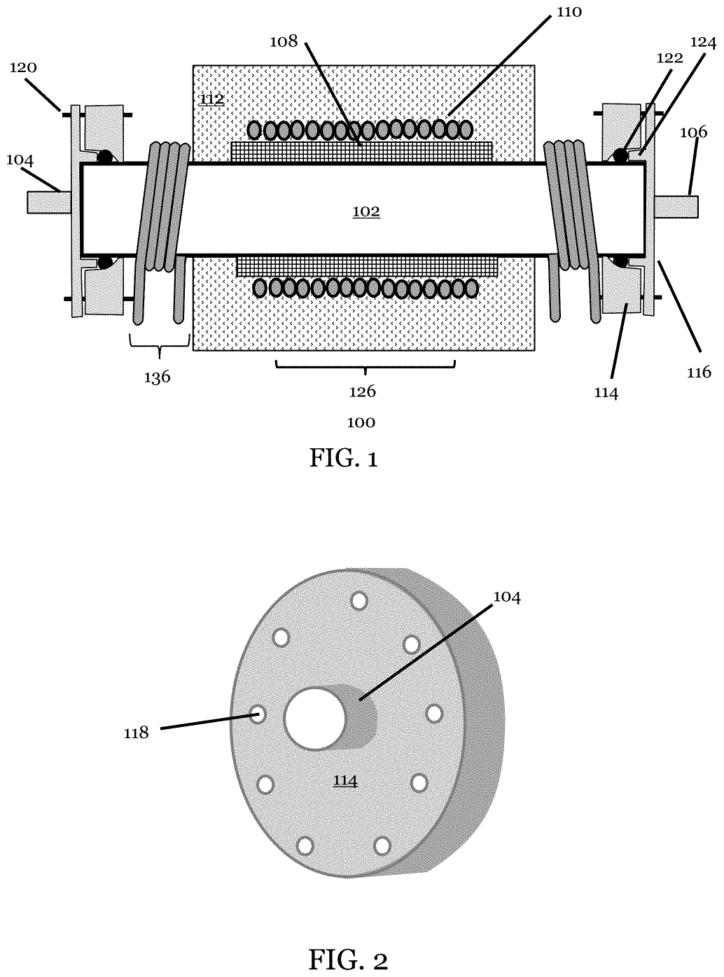

FIG. 1 is a cross section of a horizontal furnace 100 with a furnace tube 102 in accordance with an embodiment of the present application. The furnace tube 102 comprises an inner chamber 126 coupled to a fluid inlet 104 at one end configured to intake fluids such as process gases into the inner chamber 126 and coupled to a fluid outlet 106 at an opposing end configured to exhaust the fluid from the inner chamber 126. Clamping systems at the ends of the furnace tube 102 couple the furnace tube 102 to the fluid inlet 104 and to the fluid outlet 106. The clamping systems comprise of a flange clamp 114, a backing plate 116, plus ceramic sealing rope 122. The flange clamp 114 surrounds the furnace tube and is bolted to the backing plate 116. A backing plate with the fluid inlet 104 seals one end of furnace tube 102 and a backing plate 116 with the fluid outlet 106 seals the opposing end of the furnace tube. Ceramic sealing rope 122 fills a slanted groove between the flange clamp 114 and the outer surface of the furnace tube 102. When the backing plate 116 is tightened against the flange clamp 114, a metal tab 124 on the backing plate 116 compresses the ceramic sealing rope 122 between the slanted groove and the outer surface of the furnace tube 102 forming an air tight seal. Thermally conductive support material 108 surrounds the inner chamber 126 to provide support for the furnace tube 102 and also to space the heating coils no at a constant distance from the inner chamber 126. Insulating material 112 fills the space between the heating coil 110, the furnace tube 102 assembly, and the furnace cabinet. The furnace cabinet can also contain a microprocessor that controls the furnace, mass flow controllers, electronic valves, the fluid intake manifold, the fluid exhaust manifold, pressure and thermal sensors, a cooling system, plus other subsystems.

In the horizontal furnace 100 shown in FIG. 1, a quartz or Pyrex furnace tube can optionally be used in place of the furnace tube 102 constructed of metal providing additional flexibility for this furnace system.

Furnace tubes 102 constructed of metal conduct heat better than quartz or Pyrex furnace tubes. This can increase the temperature of the clamping systems on the ends of the furnace tube 102. The temperature at the clamping systems can be reduced by providing an optional cooling section 136 between the flange clamp 114 and the inner chamber 126. Cooling fluid can be circulated through the cooling section 136.

The horizontal furnace 100 may be an annealing furnace in one or more embodiments. To process semiconductor substrates in this horizontal furnace 100, the backing plate 116 can be removed from the fluid inlet 104 end of the furnace tube 102 and a substrate boat containing multiple semiconductor substrates can be inserted into the inner chamber 126 where it can rest on the bottom inside wall of the furnace tube 102 during processing. The backing plate 116 is then reassembled to seal the fluid inlet 104 end before the furnace temperature is ramped to processing temperature and process fluids are introduced into the inner chamber 126 through the fluid inlet 104.

FIG. 2 is a projection view of the backing plate 116 on the fluid inlet 104 side of the horizontal furnace wo in accordance with an embodiment. While not separately illustrated in a projection view, the fluid outlet 106 side of the horizontal furnace wo includes a similar structure as illustrated in FIG. 1. Bolt holes 118 in the backing plate 116 align with bolt holes on the flange clamp 114 to accommodate bolts 120 that secure the flange clamp 114 to the backing plate 116.

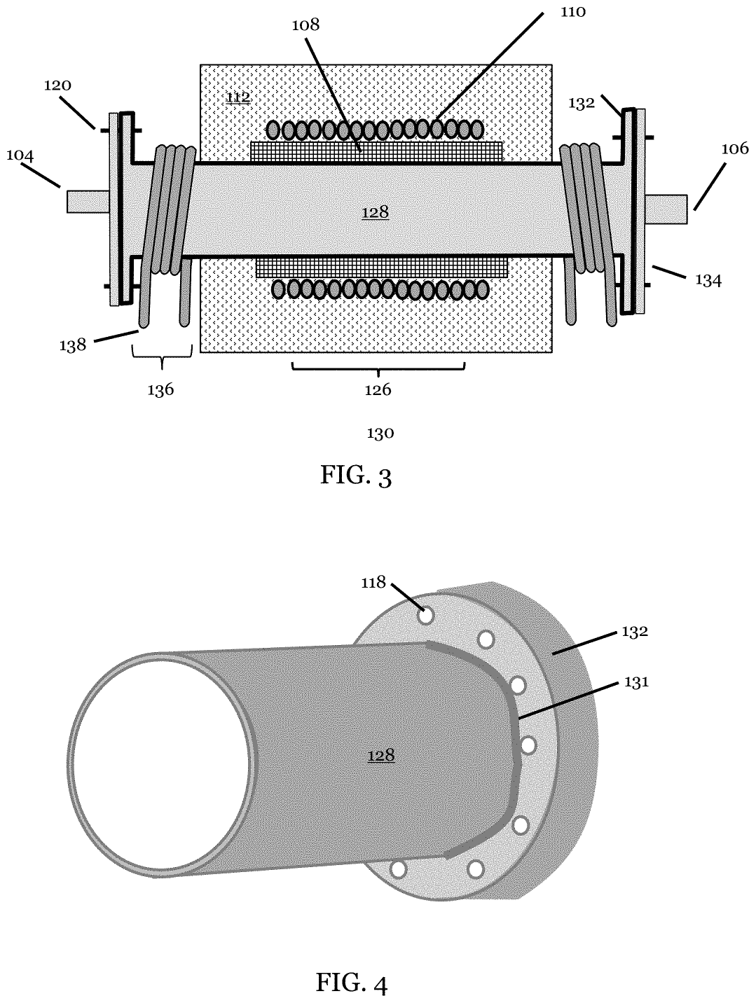

FIG. 3 is a cross section of a horizontal furnace 130 with an embodiment metal furnace tube 128 with metal tube flanges 132. Metal tube flanges 132 welded to the ends of the metal furnace tube 128 replace flange clamps 114 and ceramic sealing rope 122 in FIG. 1. The metal tab 124 used to compress the ceramic sealing rope 122 is removed from backing plate 116 in FIG. 1 to form the backing plate 134 in FIG. 3. A gasket can be inserted between the backing plate 134 and the metal tube flange 132 to create an air tight seal when the backing plate 134 is secured to the metal tube flange 132 with bolts 120.

Manufacturing cost of a metal furnace tube 128 for the horizontal furnace 130 in FIG. 3 is significantly less than the manufacturing cost of a quartz furnace tube for the horizontal furnace tube in FIG. 1. The cost of materials plus fabrication costs are significantly reduced. In addition, removal and mounting of the metal furnace tube 128 with metal tube flanges 132 takes less time and the breakage of quartz tubes is eliminated.

Metal furnace tubes 128 conduct heat better than quartz or Pyrex furnace tubes. This can increase the temperature of the clamping systems on the ends of the metal furnace tube 128. The temperature of the clamping systems can be reduced by providing an optional cooling section 136 between the metal tube flange 132 and the inner chamber 126. Cooling fluid can be circulated through the cooling section 136.

FIG. 4 is a projection view of a portion of the metal furnace tube 128 in FIG. 3. A metal tube flange 132 is welded at weld joints 131 to the open ends of the metal furnace tube 128. The weld joints 131 may form a continuous line within the inside circumference of the metal tube flanges 132 or they made be spot welded at intermittent locations. Bolt holes in the metal tube flanges 132 align with bolt holes in the backing plates 134 to accommodate bolts 120 that secure the backing plate 134 to the metal tube flange 132. A gasket can be inserted between the metal tube flange 132 and the backing plate 134 to form an air tight seal.

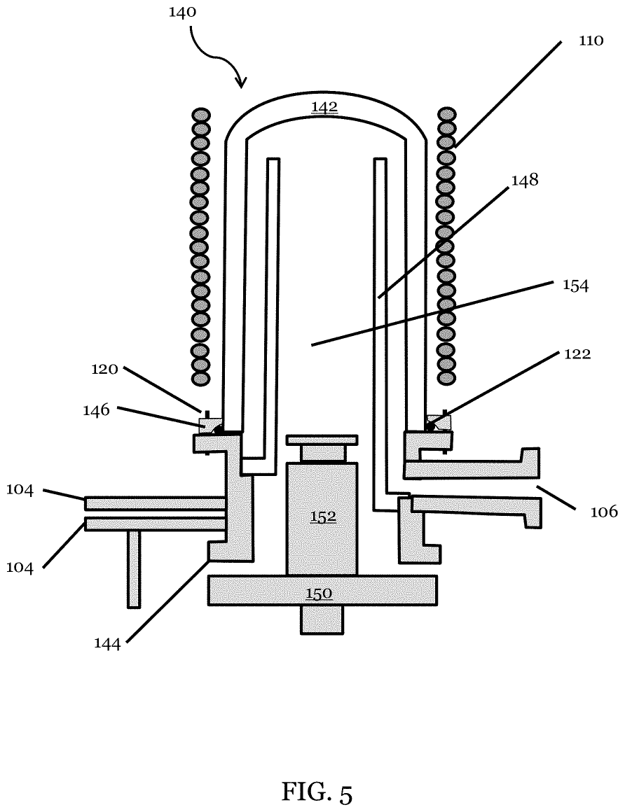

FIG. 5 is a cross section of a vertical furnace 140 with an embodiment vertical metal furnace tube 142 mounted on a base plate 144 in the furnace cabinet. The embodiment vertical metal furnace tube 142 is open at the bottom and is closed at the top. The bottom of the vertical metal furnace tube 142 is secured to the base plate 144 with a flange clamp 146 and ceramic sealing rope 122 in the same manner as is described in FIG. 1. In this vertical furnace 140, the vertical metal furnace tube 142 comprises an inner chamber 154 coupled to a fluid inlet 104 in the base plate 144. The fluid inlet 104 is configured to intake fluids such as process gases into the inner chamber 154 and coupled to a fluid outlet 106 in the base plate 144. The fluid outlet 106 is configured to exhaust the fluid from the inner chamber 154. A door 150 can be lowered to load a boat of semiconductor substrates into the vertical furnace 140 and can be raised to seal against the bottom of the base plate 144 for processing. The boat with semiconductor substrates can be positioned on a pedestal 152 on the door 150 and positioned in the inner chamber 154 when the door 150 is in the raised position. In this vertical furnace 140, a metal liner tube 148 that is open at the top surrounds the wafers with a gap between it and the vertical metal furnace tube 142, which in this case is vertical. The metal liner tube 148 redirects the flow of the process fluids to the fluid outlet 106 in the base plate 144. The vertical furnace 140 may be an annealing furnace in one or more embodiments. During processing, the process gases flow from the base plate 144 into the metal liner tube 148 and around the semiconductor substrates before exiting the top of the metal liner tube 148 and flowing past the outside of the metal liner tube 148 and out of the fluid outlet 106. Heating coils no surround the vertical metal furnace tube 142.

The vertical furnace 140 in FIG. 5 can be integrated into a furnace cabinet. The furnace cabinet can also contain a microprocessor that controls the furnace, mass flow controllers to control fluid flow, electronic valves to stop and start fluid flow, the fluid intake manifold the fluid exhaust manifold, pressure sensors, thermal sensors, a cooling system, plus other subsystems.

In the vertical furnace 140 shown in FIG. 5, a quartz or Pyrex furnace tube can optionally be used in place of the embodiment vertical metal furnace tube 142 providing additional flexibility for this furnace system.

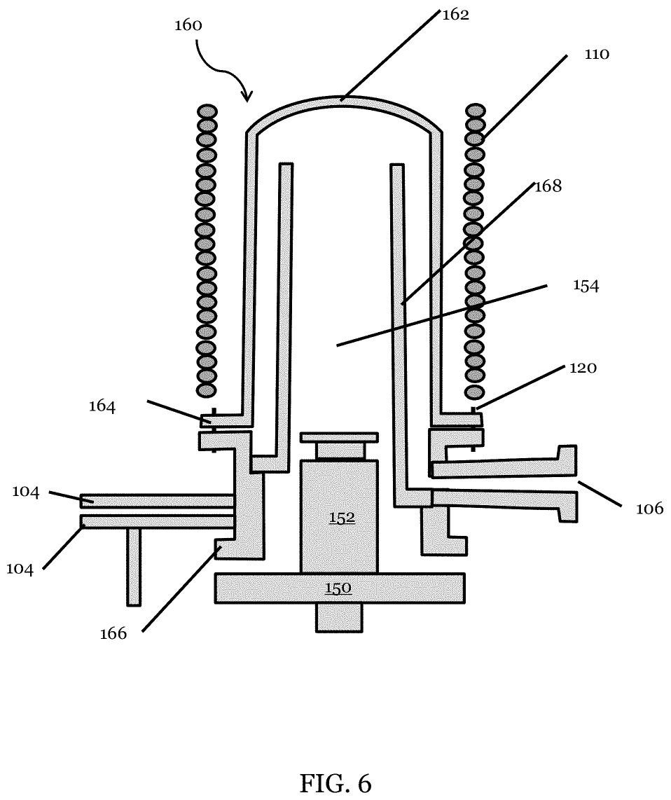

FIG. 6 is a cross section of a vertical furnace 160 with an embodiment vertical metal furnace tube 162 with metal tube flange 164. The embodiment vertical metal furnace tube 162 is open at the bottom and closed at the top. Unlike the embodiment described in FIG. 5, in this embodiment the metal tube flange 164 is welded to the open bottom of the vertical metal furnace tube 162 and is secured to the base plate 166 in the furnace cabinet with bolts 120. As in the vertical furnace 140 of FIG. 5, the fluid inlet 104 and fluid outlet 106 are located in the base plate 166. As described in FIG. 5, a metal liner tube 168 redirects the flow of the process fluid towards the fluid outlet 106. The attached metal tube flange 164 replaces the flange clamp 146 and ceramic sealing rope 122 in FIG. 5. A gasket can be inserted between the metal tube flange 164 and the base plate 166 to provide an air tight seal.

Manufacturing cost of a vertical metal furnace tube 162 for the vertical furnace 160 in FIG. 6 is significantly less than the manufacturing cost of a quartz furnace tube for the vertical furnace FIG. 5. The cost of materials plus fabrication costs are significantly reduced. In addition, maintenance costs are reduced. Removal and mounting of the vertical metal furnace tube 162 with the attached metal tube flange 164 takes less time and eliminates the breakage of a quartz furnace tube.

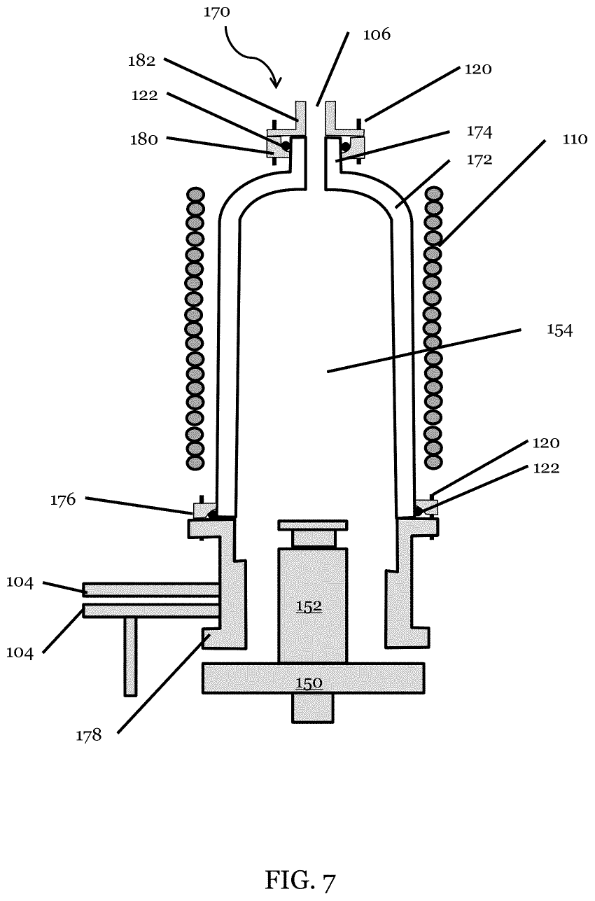

FIG. 7 is a cross section of an alternative vertical furnace 170 with an embodiment vertical metal furnace tube 172 that is an open at the bottom and open at the top. The bottom of the vertical metal furnace tube 172 is secured to the base plate 178 with a flange clamp 176 and ceramic sealing rope 122 in the same manner as is described in FIG. 1. In this vertical furnace 170, the vertical metal furnace tube 172 comprises an inner chamber 154 coupled to a fluid inlet 104 in the base plate 178, the fluid inlet 104 being configured to intake fluids such as process gases into the inner chamber 154. The inner chamber 154 is also coupled to a fluid outlet 106 at the top of the vertical metal furnace tube 172. The fluid outlet 106 is configured to exhaust the fluids from the inner chamber 154. A fluid exhaust opening 174 at the top of the vertical metal furnace tube 172 is secured to the fluid outlet 106 with a flange clamp 180 and ceramic sealing rope 122 in the same manner as is described above. A door 150 can be lowered and can be raised to seal against the bottom of the base plate 178. When the door 150 is lowered, a boat with semiconductor substrates can be positioned on a pedestal 152 on the door iso. The boat with semiconductor substrates can be positioned in the inner chamber 154 when the door 150 is raised. Unlike the vertical furnaces described in FIGS. 5 and 6, where the fluid inlet and fluid exhaust are both in the base plate, fluid in this vertical furnace flows from the base plate 178 into the vertical metal furnace tube 172 and exits through the fluid exhaust opening 174 at the top. Since in this arrangement there is no need to redirect the fluid flow, the metal liner tube 148 can be omitted. During processing the process gases flow from the base plate 178 into the inner chamber 154 and around the semiconductor substrates before exiting through the fluid exhaust opening 174 in the top of the vertical metal furnace tube 172 and the fluid outlet 106.

In the vertical furnace 170 shown in FIG. 7, a quartz or Pyrex furnace tube can optionally be used in place of the embodiment vertical metal furnace tube 172 providing additional flexibility for this furnace system.

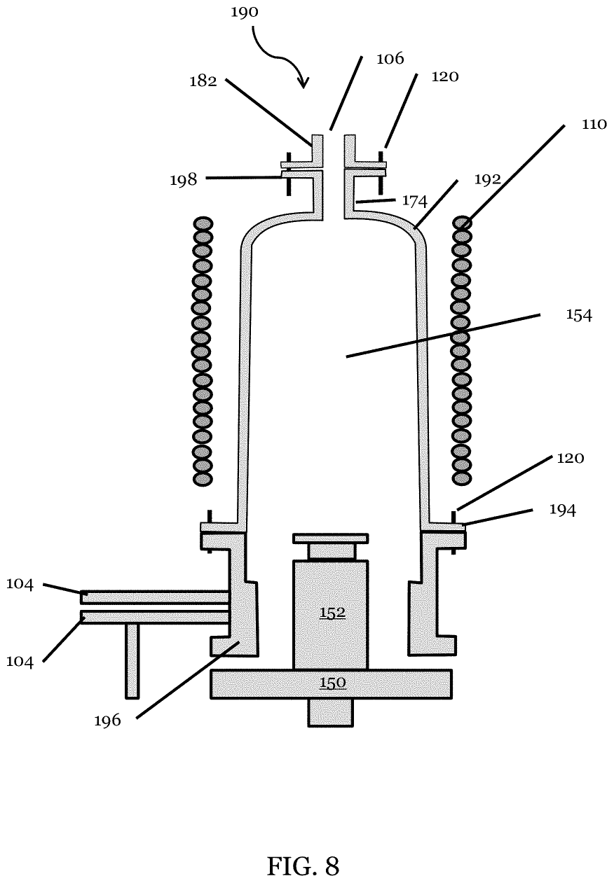

FIG. 8 is a cross section of a vertical furnace 190 with an embodiment vertical metal furnace tube 192 with metal tube flange 194 welded to the open bottom of the vertical metal furnace tube 192 and metal tube flange 198 welded to the fluid exhaust opening 174 at the top. The metal tube flange 194 welded to the open bottom of the vertical metal furnace tube 192 is secured to the base plate 196 with bolts 120. The metal tube flange 198 welded to the fluid exhaust opening 174 at the top is secured to the exhaust manifold 182 with bolts 120. The metal tube flange 194 on the base of the vertical metal furnace tube 192 replaces the flange clamp 176 and ceramic sealing rope 122 in FIG. 7. The metal tube flange 198 at the top of the vertical metal furnace tube 172 replaces the flange clamp 180 and ceramic sealing rope 122 in FIG. 7.

Manufacturing cost of a vertical metal furnace tube 192 for the vertical furnace 190 in FIG. 8 is significantly less than the manufacturing cost of a quartz furnace tube for the vertical furnace FIG. 7. The cost of materials plus fabrication costs are significantly reduced. In addition maintenance costs are greatly reduced. Removal and mounting of the vertical metal furnace tube 192 with the attached metal tube flanges, 196 and 198, takes less time and eliminates the breakage of a quartz furnace tube. Many more semiconductor wafers can be processed through the embodiment vertical metal furnace tube 192 before a tube cleaning is required.

Processing costs can be significantly reduced when metal furnace tubes are used instead of quartz or Pyrex furnace tubes. In addition to eliminating tube breakage, and in addition to the reduced time for tubes to be exchanged during maintenance, the time between tube cleanings can be significantly extended. Differences in the coefficient of thermal expansion (CTE) of the thin film being deposited with the CTE of the furnace tube limits the number of depositions. Stress buildup due to CTE mismatch can cause delamination, which can cause particle contamination.

TABLE 1

| | CTE |
|---|---|
| MATERIAL | x 10-7/° C. |
| fused quartz | .55 |
| alumina | 8.1 |
| titanium nitride | 9.35 |
| titanium | 8.75 |
| aluminum | 23 |
| nickel | 17.5 |
| stainless steel 310 | 14.4 |

CTE's for various materials are given in Table 1. The CTE mismatch between deposited thin films (the film being coated on the semiconductor wafers) such as alumina and titanium nitride and a quartz tube is significantly larger than the mismatch created when the furnace tubes are made of aluminum, titanium, nickel, and stainless steel 310. The lower CTE mismatch enables more layers of thin films such as alumina or titanium nitride to be deposited before the onset of delamination. This improves furnace uptime by enabling more lots to be processed between tube cleanings. In an example arrangement, more than double the thickness of aluminum oxide can be deposited in an aluminum furnace tube with no delamination than can be deposited in a quartz furnace tube. This means that more than twice the number of semiconductor substrates can be processed before a furnace tube change and cleaning is required.

In one embodiment furnace system and method, aluminum oxide is deposited using a chemical vapor deposition (CVD) process in a furnace tube made of aluminum or an aluminum alloy.

In another embodiment furnace system and method, titanium nitride is deposited using CVD process in a furnace tube being made of titanium or a titanium alloy.

Unlike brittle quartz tubes, the inner surface of metal furnace tubes can be roughened by bead blasting to enhance adhesion of the thin film to the inner surface. Roughening the inner surface increases surface area. This improves adhesion between the deposited thin film and the furnace tube. Roughening the inner surface enables more layers of thin film to be deposited before the onset of delamination. Manufacturing cost is reduced because more lots can be processed before a tube change is required. With bead blasting the inside surface of metal furnace tubes can be roughened to a roughness Ra of greater than about 0.1.

The furnace heating coils no can emit mobile ions such as sodium, potassium, iron, and calcium. These ions can contaminate and degrade integrated circuits. In various embodiments, a barrier layer of thin film is deposited to coat the inside wall of the metal furnace tubes discussed in various embodiments and prevent these mobile ions from reaching the semiconductor substrates. Barrier materials can include silicon nitride, titanium nitride, tantalum nitride, and aluminum oxide.

Unlike, quartz tubes that are insulating, in various embodiments, metal furnace tubes can be configured to actively remove ion contamination. Mobile ions that are harmful to integrated circuits tend to be positively charged. To reduce positive ion contamination, the metal furnace tube can be electrically isolated from the furnace cabinet and can be biased to a fixed potential relative to the furnace cabinet. The fixed potential can attract ion contaminants to the inner walls of the metal furnace tube and away from the semiconductor substrates.

In various embodiments, furnaces described in various embodiment of FIGS. 1-8 may be a chemical vapor deposition (CVD), an atomic layer deposition (ALD) furnace, or an annealing furnace used in heat treatment.

The cost savings when an embodiment metal furnace tube is used to replace a quartz tube in a high pressure, hot wall, batch furnace can be significant. High pressure processes can range from a few atmospheres to a dozen atmospheres or more. The final processing step in most semiconductor manufacturing flows is to anneal the substrates in hydrogen or forming gas (nitrogen plus hydrogen). This stabilizes the turn on voltage of transistors and narrows the turn on voltage distribution. To reduce processing time this anneal (often referred to as sintering) can be performed at elevated pressures. Since quartz cannot withstand large pressure differentials, the pressure of the ambient fluid surrounding the high pressure quartz furnace tube must be equal to the pressure of the process fluids inside the quartz furnace tube. This requires a special fluid pressure equalization system in the high pressure furnace. In high pressure quartz tube furnaces, the entire quartz furnace tube plus the tube support and the heating element are housed in a separate metal chamber capable of withstanding multiple atmospheres of pressure. An embodiment high pressure metal furnace tube can withstand the large pressure differentials required by high pressure processes.

Advantageously, in or more embodiments, the metal furnace tube has a thick metal wall that is able to withstand a pressure differential between the outside and the inside of the metal furnace tube of up to 20 atmospheres. Accordingly, in one embodiment, the plurality of substrates are loaded into an inner chamber of the metal furnace tube that is made of stainless steel, nickel, or a nickel alloy and an annealing process may be performed on the plurality of substrates while pressurizing the inner chamber of the metal furnace tube to a first pressure and the furnace outside of the metal furnace tube to a second pressure different from the first pressure, where a difference between the first pressure and the second pressure is in the range of 1 atm to about 10 atm. In another embodiment, the difference between the first pressure and the second pressure is in the range of 1 atm to about 20 atm. This eliminates the need for the separate metal high pressure chamber and also eliminates need for the special fluid pressure equalization system. Eliminating the separate high pressure chamber and fluid pressure equalization system with an embodiment high pressure, hot wall, metal furnace tube significantly reduces cost of the high pressure furnace.

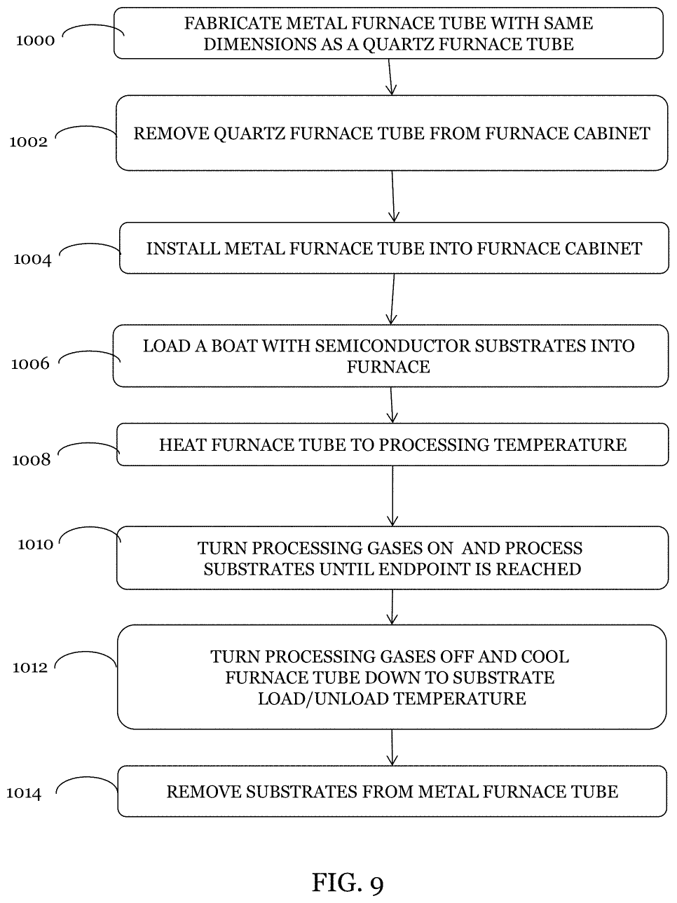

FIG. 9 is a flow diagram describing a method for forming an apparatus comprising, a furnace cabinet with a metal furnace tube and a method for processing a batch of semiconductor substrates. In this arrangement a metal furnace tube is fabricated with the same dimensions as a quartz furnace tube so that the quartz furnace tube can be replaced with the metal furnace tube with no changes to the furnace cabinet.

As illustrated in the first method block moo, a metal furnace tube configured with an inner chamber is fabricated with the same dimensions as a quartz furnace tube.

As next illustrated in the second 1002 and third 1004 method blocks, a quartz furnace tube is removed from the furnace cabinet and the metal furnace tube is installed. In this arrangement, as described in FIGS. 1, 5, and 7, the clamping system that couples the quartz furnace tube to the metal fluid inlet and metal fluid outlet is used to couple the metal furnace tube to the metal fluid inlet 104 and metal fluid outlet 106. The clamping system comprises of a tube flange on the end of the metal furnace tube that mates to a base plate or to a flange back plate in the furnace cabinet.

As next illustrated in the fourth method block 1006, a boat containing semiconductor substrates such as semiconductor wafers is loaded into the inner chamber of the metal furnace tube.

Referring to the fifth method block 1008, the furnace tube and the semiconductor substrates are heated to processing temperature.

As illustrated in the sixth method block 1010, the flow of the process fluids is initiated to process the semiconductor substrates until the endpoint is reached.

Referring to the seventh method block 1012, the flow of the process fluids is stopped and the temperature is ramped down to load/unload temperature.

Referring to the eighth method block 1014, the semiconductor substrates are unloaded from the metal furnace tube.

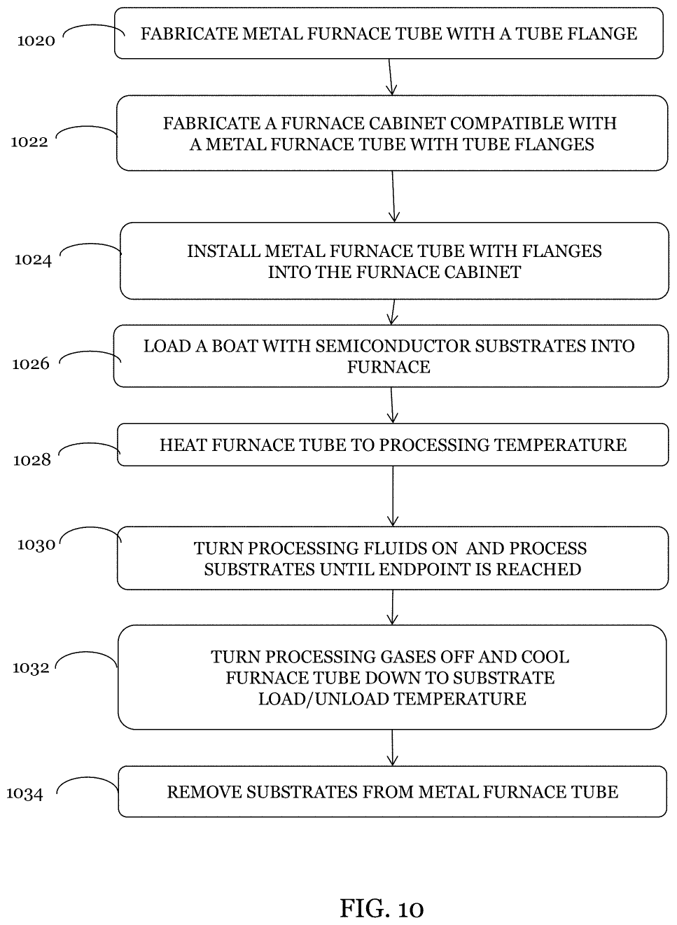

FIG. 10 is a flow diagram of a method for forming an apparatus comprising, a furnace cabinet with a flanged metal furnace tube and processing a batch of semiconductor substrates. In this arrangement changes are made to the metal furnace tube and to the furnace cabinet to reduce furnace system cost and to reduce cost of ownership.

As illustrated in the first method block 1020, a metal furnace tube is fabricated and configured with an inner chamber and configured with a tube flange welded to the end of the metal furnace tube. The tube flange is configured to mate with a base plate or a flange back plate in the furnace cabinet as discussed in FIGS. 3, 6, and 8.

As illustrated in the second method block 1022, a furnace cabinet is fabricated that is compatible with a metal furnace tube with a tube flange. The furnace cabinet is configured with a heating element that surrounds the inner chamber.

As illustrated in the third method block 1024, the metal furnace tube with tube flanges is installed into the furnace cabinet that is modified to be compatible with the metal furnace tube with tube flanges.

As illustrated in the fourth method block 1026, a boat containing semiconductor substrates such as semiconductor wafers is loaded into the inner chamber of the metal furnace tube.

As illustrated in the fifth method block 1028, the furnace tube and the semiconductor substrates are heated to processing temperature.

As illustrated in the sixth method block 1030, the flow of the process fluids is initiated to process the semiconductor substrates until the endpoint is reached.

As illustrated in the seventh method block 1032, the flow of the process fluids is stopped and the temperature is ramped down to load/unload temperature.

As illustrated in the eighth method block 1034, the semiconductor substrates are unloaded from the metal furnace tube.

Metal furnace tubes offer many advantages in terms of initial furnace system cost, furnace tube replacement cost, ease of handling, reduced maintenance cost, reduced breakage, and reduced manufacturing costs. Metal furnace tubes can be designed to replace existing quartz furnace tubes or can be designed with flanges to additionally reduce the initial cost of the furnace system and to reduce the cost of maintenance.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

What is claimed is:

1. An apparatus comprising:
a metal furnace tube having an open first end and an opposite second end, the metal furnace tube comprising an inner chamber, a fluid inlet configured to intake a fluid into the inner chamber, and a fluid outlet configured to exhaust the fluid from the inner chamber, the inner chamber configured to support a plurality of substrates within the metal furnace tube;
a first base plate or flange back plate coupling the fluid inlet to the inner chamber;
a second base plate or flange back plate coupling the fluid outlet to the inner chamber; and
a furnace comprising a heater configured to heat the metal furnace tube, the metal furnace tube being mounted within the furnace and the heater being disposed outside the metal furnace tube.

2. The apparatus of claim 1, wherein the furnace is a chemical vapor deposition (CVD), an atomic layer deposition (ALD) furnace, or an annealing furnace.

3. The apparatus of claim 1, wherein an inside surface of the metal furnace tube is roughened to have a surface roughness of at least 0.1 Ra.

4. The apparatus of claim 1, wherein an inside surface of the metal furnace tube is coated with a layer comprising silicon nitride, titanium nitride, tantalum nitride, or aluminum oxide.

5. The apparatus of claim 1, wherein the metal furnace tube comprises aluminum, nickel, titanium, tungsten, or stainless steel.

6. The apparatus of claim 1, wherein the metal furnace tube is electrically isolated from the furnace and configured to be biased to a fixed potential relative to the furnace.

7. The apparatus of claim 1, wherein the metal furnace tube has a thick metal wall rated for pressures of between 1 atm. and about 20 atm.

8. The apparatus of claim 1, further comprising:
a metal tube flange disposed at the first end of the metal furnace tube; and
a base plate or a flange back plate disposed in the furnace configured to mate with the metal tube flange.

9. The apparatus of claim 8, wherein the metal furnace tube further comprises a cooling section near the metal tube flange.

10. The apparatus of claim 8, wherein the furnace is a horizontal furnace chamber and the metal furnace tube is a horizontal metal furnace tube, and wherein the fluid inlet with a first flange back plate is disposed at the first end and the fluid outlet with a second flange back plate is disposed at the second end.

11. The apparatus of claim 8, wherein the furnace is a vertical furnace and the metal furnace tube comprises a tube flange at a base of the metal furnace tube and the second end of the metal furnace tube is closed, and wherein the tube flange mates with the base plate in the vertical furnace and the fluid inlet and the fluid outlet are located within the base plate and extend through the base plate.

12. The apparatus of claim 8, wherein the furnace is a vertical furnace and the metal furnace tube comprises an inlet tube flange at a base of the metal furnace tube and with an outlet tube flange at the second end of the metal furnace tube.

13. A method comprising:
having a metal furnace tube, the metal furnace tube comprising an inner chamber to house a plurality of substrates, a fluid inlet configured to intake a fluid into the inner chamber, and a fluid outlet configured to exhaust the fluid from the inner chamber;
having a tube flange at a first end of the metal furnace tube;
mounting the metal furnace tube in a furnace configured to heat the metal furnace tube;
having a base plate or a flange back plate in the furnace; and
mating the tube flange with the base plate or the flange back plate.

14. The method of claim 13, further comprising roughening an inside surface of the metal furnace tube by blasting the inside surface with beads.

15. The method of claim 13, further comprising depositing a barrier layer of aluminum oxide, silicon nitride, silicon oxynitride, titanium nitride, or tantalum nitride on an inside surface of the metal furnace tube.

16. The method of claim 13, further comprising:
loading the plurality of substrates into the metal furnace tube, the metal furnace tube being made of aluminum or an aluminum alloy, the plurality of substrates being loaded into the inner chamber, and performing a chemical vapor deposition process to deposit aluminum oxide over the plurality of substrates; or
loading the plurality of substrates into the metal furnace tube, the metal furnace tube being made of titanium or a titanium alloy, the plurality of substrates loaded into the inner chamber, and performing a chemical vapor deposition process to deposit titanium nitride over the plurality of substrates.

17. A method comprising:
removing a glass or quartz furnace tube from a furnace from a tube mounting location of the furnace;
mounting a metal furnace tube in the furnace at the tube mounting location, the metal furnace tube comprising an inner chamber to house a plurality of substrates, a fluid inlet configured to intake a fluid into the inner chamber, and a fluid outlet configured to exhaust the fluid from the inner chamber; and
attaching a tube flange at a first end of the metal furnace tube to a base plate or to a flange back plate in the furnace.

18. The method of claim 17, further comprising determining that the glass or quartz furnace tube has to be replaced, wherein the removing is performed based on the determining.

19. The method of claim 17, further comprising:
loading the plurality of substrates into the metal furnace tube, the metal furnace tube being made of aluminum or an aluminum alloy, the plurality of substrates loaded into the inner chamber, and performing a chemical vapor deposition process to deposit aluminum oxide over the plurality of substrates; or
loading the plurality of substrates into the metal furnace tube, the metal furnace tube being made of titanium or a titanium alloy, the plurality of substrates being loaded into the inner chamber; and performing a chemical vapor deposition process to deposit titanium nitride over the plurality of substrates; or
loading the plurality of substrates into the metal furnace tube, the metal furnace tube being made of stainless steel, nickel, or a nickel alloy, the plurality of substrates being loaded into the inner chamber; and performing a sintering process on the plurality of substrates.

20. The method of claim 17, further comprising:
loading the plurality of substrates into the inner chamber of the metal furnace tube, the metal furnace tube being made of stainless steel, nickel, or a nickel alloy; and
performing an annealing process on the plurality of substrates while pressurizing the inner chamber of the metal furnace tube to a first pressure and the furnace to a second pressure different from the first pressure, wherein a difference between the first pressure and the second pressure is in the range of 1 atm to about 20 atm.
